(19) United States
(12) Patent Application Publication
(10) Pub. No.: US 2025/0204280 A1
(43) Pub. Date: Jun. 19, 2025

(54) Differential Coupling of Quantum Bit Chips

(71) Applicant: International Business Machines Corporation, Armonk, NY (US)

(72) Inventors: Muir KUMPH, Croton-on-Hudson, NY (US); Joseph Robert SUTTLE, Chappaqua, NY (US); John BLAIR, Katonah, NY (US)

(21) Appl. No.: 18/539,430

(22) Filed: Dec. 14, 2023

(51) Int. Cl. H10N 69/00; H01L 23/00; H01L 25/16; H10N 60/12

(52) U.S. Cl. CPC H10N 69/00; H01L 25/16; H10D 1/714; H10D 1/716; H01L 24/16; H01L 2224/16157; H10N 60/12

(57) ABSTRACT

A package structure comprises a first quantum bit chip and a second quantum bit chip bonded to an interposer, and a differential coupling bus. The differential coupling bus is configured to differentially couple the first quantum bit chip and the second quantum bit chip at least in part through differential transmission lines disposed on the interposer.

### BACKGROUND

This disclosure relates generally to superconducting quantum computing systems and, in particular, techniques for coupling quantum bit chips to construct, e.g., a quantum computer. A quantum computing system can be implemented using superconducting circuit quantum electrodynamics (cQED) architectures that are constructed using quantum circuit components such as, e.g., superconducting quantum bits and other types of superconducting quantum devices that are controlled using microwave and/or flux bias control signals. In general, superconducting quantum bits (qubits) are electronic circuits which are implemented using components such as superconducting tunnel junctions (e.g., Josephson junctions), superconducting quantum interference devices (SQUIDs), inductors, and/or capacitors, etc., and which behave as quantum mechanical anharmonic (non-linear) oscillators with quantized states, when cooled to cryogenic temperatures. A qubit can be effectively operated as a two-level system in a computational subspace comprising a ground state |0> and a first excited state |1> of the qubit, due to the anharmonicity imparted by a non-linear inductor element (e.g., Josephson junction inductance) of the qubit, which allows the ground and the first excited states to be uniquely addressed at a transition frequency of the qubit, without significantly disturbing higher excited states of the qubit (e.g., |2>, |3> etc.).

Various types of quantum information processing algorithms can be implemented using a superconducting quantum processor which comprises multiple superconducting qubits which can be coherently controlled, placed into quantum superposition states, exhibit quantum interference effects, and become entangled with one another, by applying various types of quantum gate operations (e.g., single-qubit gate operations, two-qubit gate operations, etc.) to the superconducting qubits. As quantum processors are scaled with increasing numbers of superconducting qubits and higher integration densities, a primary challenge is being able to scale up the number of qubits without introducing additional channels of noise and unwanted exchange interactions that result in correlated gate errors.

In this regard, techniques for scaling quantum processors include modular approaches in which a plurality of high-yielding quantum bit chips are individually fabricated and packaged together to form larger-scale quantum processors. Such smaller quantum bit chips are easier to fabricate and can be screened for defects before being packaged together. While modular architectures allow larger quantum processor devices to be built from smaller units, it is non-trivial to couple individual qubit chips together using quantum coherent interconnects and coupling schemes that are sufficiently immune to noise that results of unwanted package modes, wherein such noise can perturb quantum bit states and introduce gate errors when performing two-qubit gate operations between quantum bits that are disposed on different quantum bit chips.

### SUMMARY

Exemplary embodiments of the disclosure include package structures which comprise quantum bit chips that are coupled using differential coupling structures. For example, an exemplary embodiment includes a package structure which comprises a first quantum bit chip and a second quantum bit chip bonded to an interposer, a differential coupling bus that is configured to differentially couple the first quantum bit chip and the second quantum bit chip at least in part through differential transmission lines disposed on the interposer.

Advantageously, the differential coupling serves to provide immunity to noise that results from package modes that may exist between separate quantum bit chips disposed on a common interposer.

In another exemplary embodiment, as may be combined with the preceding paragraphs, the differential coupling bus comprises a tunable coupler that is configured to control interactions between a first quantum bit on the first quantum bit chip and a second quantum bit on the second quantum bit chip.

Another exemplary embodiment includes a package structure which comprises a first quantum bit, a second quantum bit, and a differential coupling bus. The first quantum bit comprises a first pad and a second pad. The second quantum bit comprises a third pad and a fourth pad. The differential coupling bus is configured to differentially couple the first quantum bit and the second quantum bit. The differential coupling bus comprises a first electrical path which capacitively couples the first pad and the third pad, and a second electrical path which capacitively couples the third pad and the fourth pad. The first electrical path comprises a tunable coupler, which is serially connected in the first electrical path, and which is configured to control interactions between the first quantum bit and the second quantum bit. The second electrical path is capacitively coupled to the tunable coupler.

In another exemplary embodiment, as may be combined with the preceding paragraphs, the tunable coupler comprises a flux-tunable quantum bit.

Another exemplary embodiment includes a package structure which comprises a first quantum bit, a second quantum bit, a tunable coupler, and a differential coupling bus. The first quantum bit comprises a first pad and a second pad. The second quantum bit comprises a third pad and a fourth pad. The tunable coupler is configured to control interactions between the first quantum bit and the second quantum bit. The differential coupling bus is coupled to and between the first quantum bit and the second quantum bit. The differential coupling bus comprises a first electrical path which capacitively couples the first pad and the third pad, and a second electrical path which capacitively couples the third pad and the fourth pad. The tunable coupler is capacitively coupled to both the first electrical path and the second electrical path.

Other embodiments will be described in the following detailed description of exemplary embodiments, which is to be read in conjunction with the accompanying figures.

### BRIEF DESCRIPTION OF THE DRAWINGS

FIG. 1 schematically illustrates a package structure comprising quantum bit chips and a differential coupling bus for coupling the quantum bit chips, according to an exemplary embodiment of the disclosure.

FIG. 2A schematically illustrates an exemplary superconducting quantum bit which can be implemented on a quantum bit chip of a package structure, according to an exemplary embodiment of the disclosure.

FIG. 2B schematically illustrates an exemplary tunable coupler which can be implemented on a quantum bit chip of a package structure, according to an exemplary embodiment of the disclosure.

FIG. 3A is a schematic perspective view of a package structure comprising quantum bit chips and a differential coupling bus for coupling the quantum bit chips, according to an exemplary embodiment of the disclosure.

FIG. 3B is a schematic perspective view of a package structure comprising quantum bit chips and a differential coupling bus for coupling the quantum bit chips, according to another exemplary embodiment of the disclosure.

FIG. 4 is a schematic plan view of a package structure comprising quantum bit chips and a differential coupling bus for coupling the quantum bit chips, according to another exemplary embodiment of the disclosure.

FIGS. 5A and 5B schematically illustrate a package structure comprising quantum bit chips and a differential coupling bus for coupling the quantum bit chips, according to another exemplary embodiment of the disclosure.

FIG. 6 is a schematic plan view of a package structure comprising quantum bit chips and a differential coupling bus for coupling the quantum bit chips, according to another exemplary embodiment of the disclosure.

FIG. 7 illustrates a flow diagram of a process for fabricating a modular package structure, according to an exemplary embodiment of the disclosure.

FIG. 8 schematically illustrates a quantum computing system which comprises a quantum processor that is implemented using a modular package structure, according to an exemplary embodiment of the disclosure.

### DETAILED DESCRIPTION

Exemplary embodiments of the disclosure will now be described in further detail with regard to techniques for packaging multiple qubit chips to construct large scale quantum processors and, in particular, techniques for coupling qubits that are fabricated on different qubit chips. In general, the exemplary coupling techniques as discussed herein enable differential coupling between qubit chips to facilitate the construction of a high performance, scalable modular architecture where multiple qubit chips are packaged together to construct a quantum processor wherein the chip-to-chip coupling and qubit-qubit coupling is robust against unwanted noise that results from interactions of package modes that may exist between adjacent qubit chips.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise quantum circuit elements (e.g., quantum bits, SQUIDS, tunable couplers, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

In addition, the terms “quantum bit chip” or “qubit chip” or “quantum chip” as used herein refer to a die (e.g., semiconductor die) which comprises a superconducting electronic integrated circuit comprising various superconducting components such as qubits, tunable couplers, ground planes, signal coplanar waveguides, and resonators, etc. A plurality of dies having the same and/or different configurations of superconducting electronic integrated circuits, can be fabricated on a wafter (e.g., semiconductor wafer), wherein the individual dies can be diced (cut) from the wafer using a die singulation process to provide singulated dies which can be packaged together to construct a modular quantum processor architecture. The terms “quantum bit chip,” “qubit chip,” “quantum chip,” and “die” are synonymous terms and used interchangeably herein. Moreover, the terms “non-galvanic coupling” or “non-galvanic connection” as used herein refer to non-direct electrical connections, e.g., a connection that is achieved via capacitive coupling, inductive coupling, optical coupling, combinations thereof, etc.

As noted above, for large-scale quantum computation, a quantum processor comprising an array of superconducting qubits can utilize tunable couplers to dynamically control intra-chip qubit-qubit interactions to, e.g., enable high-fidelity two-qubit gate operations (e.g., entanglement operations). On the other hand, a primary challenge in developing a modular quantum processor architecture involves the implementation of high-fidelity, low-latency quantum inter-chip coupling between adjacent qubit chips and in particular, enabling controlled coupling between qubits that are fabricated on different qubit chips to provide high-fidelity two-qubit gate operations between qubits disposed on separate qubit chips. As superconducting quantum systems increase in size, the microwave mode frequencies of the system enclosures are reduced in frequency, which can lead to unwanted interaction by such package modes with qubits and couplers in the system. Exemplary embodiments of the disclosure implement tunable couplers in conjunction with differential coupling components to implement inter-chip coupling of separate qubit chips, and to mediate interactions between qubits disposed on separate qubit chips. The differential coupling schemes as disclosed herein are configured for connecting two or more quantum bit chips or modules, while providing immunity to package noise caused by microwave package modes.

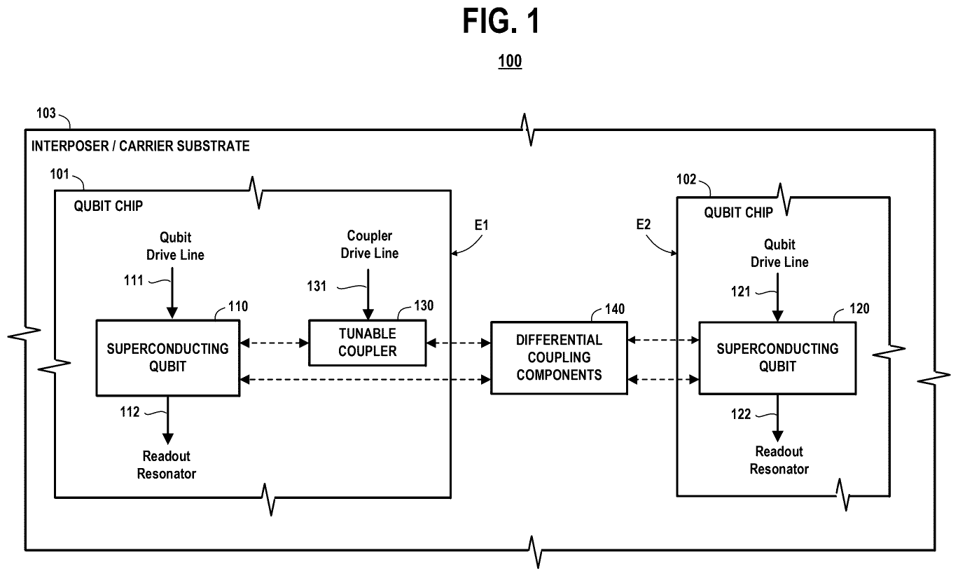

For example, FIG. 1 schematically illustrates a package structure comprising quantum bit chips and a differential coupling bus for coupling the quantum bit chips, according to an exemplary embodiment of the disclosure. In particular, FIG. 1 schematically illustrates a package structure 100 comprising a first qubit chip 101, a second qubit chip 102, and an interposer 103 (e.g., carrier substrate). In some embodiments, the first and second qubit chips 101 and 102 are flip-chip bonded to the interposer 103 using solder bumps (e.g., indium solder bumps), with a small gap between respective edges E1 and E2 of the first and second qubit chips 101 and 102. The first qubit chip 101 comprises a first superconducting qubit 110 (or first qubit 110) which is disposed in proximity to the edge E1 of the first qubit chip 101. The second qubit chip 102 comprises a second superconducting qubit 120 (or second qubit 120). In addition, the first qubit chip 101 comprises a superconducting tunable coupler 130 (or tunable coupler 130), which is coupled to the first qubit 110 and the second qubit 120, and which is configured to control interactions between the first qubit 110 and the second qubit 120, as discussed in further detail below. The gap between respective edges E1 and E2 of the first and second qubit chips 101 and 102 can be in a range of about 100 microns (μm) to about 300 millimeters (mm), or less than 100 μm in some applications.

The interposer 103 comprises an inter-chip coupling network comprising differential coupling components 140 that enable differential coupling of the first and second qubit chips 101 and 102. In some embodiments, the differential coupling is implemented using differential transmission lines formed on the interposer 103 and non-galvanic connections to connect the differential transmission lines to components on the first and second qubit chips 101 and 102. In other embodiments, the differential coupling is implemented using differential transmission lines formed on the interposer 103 and a combination of non-galvanic connections and galvanic connections to connect the differential transmission lines to components on the first and second qubit chips 101 and 102.

For example, in some embodiments, the differential coupling components 140 comprise air gap capacitors and one or more differential lines, which are formed on the interposer 103 to provide non-galvanic and differential coupling (e.g., capacitive coupling) of the first and second qubit chips 101 and 102. More specifically, in some embodiments, the differential coupling components 140 comprise air gap capacitors and differential lines that are configured to couple the tunable coupler 130 to the first qubit 110, the details of which will be explained in further detail below. In addition to capacitive coupling, non-galvanic and differential coupling between the first and second qubit chips 101 and 102 can be implemented through inductive coupling, resonant coupling, and any combination of capacitive, inductive, and/or resonant coupling. For example, inductive coupling can be implemented using a pair of wires leading to an inductor loop, and through pairs of co-planar waveguide resonators which could give resonant enhancement of coupling near the mode frequencies of the resonators. While not specifically shown in FIG. 1, in some embodiments, the interposer 103 comprises other circuit components as desired for a given package structure and given application, such as components to provide microwave shielding, circuitry to interface with qubits and tunable couplers on the individual qubit chips, signal routing for package input/output, ground planes, etc.

Furthermore, as schematically shown in FIG. 1, the package structure 100 comprises a plurality of control lines including, but not limited to, qubit drive lines 111 and 121, and a coupler drive line 131 (e.g., flux bias control line), and qubit readout lines 112 and 122 (e.g., readout resonators). In some embodiments, the qubit drive lines 111 and 121 are coupled (e.g., capacitively coupled via capacitors) to the first and second qubits 110 and 120, respectively. In some embodiments, the qubit drive lines 111 and 121 are configured to apply control signals (e.g., microwave pulse signals) to independently change the states of the respective first and second qubits 110 and 120 (e.g., single-qubit gate operations). In particular, the qubit drive lines 111 and 121 are utilized to, e.g., apply microwave control signals to drive single-qubit X-rotation gates and single-qubit Y-rotation gates, and perform other functions as discussed herein. As is known in the art, the state of a qubit can be changed by applying a microwave control signal (e.g., control pulse) with a center frequency equal to a transition frequency (generally denoted f₀₁) of the qubit, wherein the transition frequency f₀₁ corresponds to an energy difference between the ground state |0> and excited state |1> of the qubit. In addition, the axis of rotation about a given axis of the Bloch sphere (e.g., X-axis and/or Y-axis) and the amount (angle) of such rotation are based, respectively, on the phase of the microwave control signal, and the amplitude and duration of the microwave control signal.

The coupler drive line 131 is coupled to the tunable coupler 130 and is configured to apply a control signal to tune the frequency of the tunable coupler 130. The coupler drive line 131 can be capacitively coupled or mutually coupled to the tunable coupler, depending on the circuit configuration of the tunable coupler 130. The tunable coupler 130 is configured to mediate the interactions between the first and second qubits 110 and 120, for different types of gate operations. The first and second qubits 110 and 120 and the tunable coupler 130 are coupled through exchange-type interactions. The interaction strength of the first and second qubits 110 and 120 depends on the frequency of the tunable coupler 130, wherein coupler-mediated two-qubit gate operations are implemented by dynamically tuning the frequency of the tunable coupler 130 to achieve a desired interaction between the first and second qubits 110 and 120.

For example, assume that the first and second qubits 110 and 120 have respective transition frequencies of f_{q1} and f_{q2} that are detuned by an amount Δ₁₂=f_{q2}−f_{q1}. The tunable coupler 130 can be dynamically tuned (via a coupler control signal applied on the coupler drive line 131) to operate in a first state (e.g., “OFF” state or “deactivated” state) or a second state (e.g., “ON” state or “activated” state) by changing a frequency (generally denoted as f_{Coupler}) of the tunable coupler 130 between a first (OFF) frequency (denoted f_{c-off}), and a second (ON) frequency (denoted f_{C-ON}). The qubit transition frequencies f_{q1} and f_{q2} are detuned from the coupler frequency f_{C-ON} by respective amounts denoted as Δ_{1C} and Δ_{2C}.

In the “OFF” state, the tunable coupler 130 essentially serves to decouple the first and second qubits 110 and 120 by suppressing interaction (static or otherwise) between the first and second qubits 110 and 120. In some embodiments, as explained in further detail below, the tunable coupler 130 comprises a flux-tunable coupler that is maintained in an OFF state by applying a DC flux bias signal (DC current) on the coupler drive line 131. The suppressed residual coupling (e.g., suppressed static ZZ interaction) between modes of the first and second qubits 110 and 120 is due to a relatively large detuning between the off frequency f_{c-off} of the tunable coupler 130 and the operating frequencies (e.g., transition frequencies of f_{q1} and f_{q2}) of the first and second qubits 110 and 120. In other words, the detuning between the tunable coupler 130 and the first and second qubits 110 and 120 serves to significantly suppress any direct longitudinal coupling between the first and second qubits 110 and 120 and, thus, the state of one qubit will not affect the transition frequency of the other qubit. In this regard, when the tunable coupler 130 is in the OFF state, the first and second qubits 110 and 120 are essentially decoupled with substantially no quantum cross-talk between first and second qubits 110 and 120. This allows single-qubit gate operations to be independently performed on the first and second qubits 110 and 120 without the inducement of coherent errors during such single-qubit gate operations that may otherwise result from the ZZ interaction or direct exchange interactions between the first and second qubits 110 and 120.

On the other hand, the “ON” state of the tunable coupler 130 enables the first and second qubits 110 and 120 to be exchange coupled with the tunable coupler 130 which, in turn, enables/facilitates exchange coupling (e.g., ZZ interaction) between the first and second qubits 110 and 120, which are capacitively coupled to the tunable coupler 130. In some embodiments, as explained in further detail below, the tunable coupler 130 is placed into an ON state by applying a pulse flux bias signal (on top of the DC flux bias signal) to the tunable coupler 130 to enable a controlled amount of exchange interaction (entanglement) between the states of the first and second qubits 110 and 120. In this manner, the tunable coupler 130 is configured to facilitate two-qubit entanglement gates including, but not limited to longitudinal two-qubit gates (e.g., a controlled-phase gate (referred to as CPHASE gate or CZ gate)) and transversal two-qubit gates (e.g., SWAP or iSWAP gates).

To perform an entanglement gate operation, the tunable coupler 130 can be driven to the ON frequency f_{C-ON} which is near, e.g., a transition frequency or resonant frequency, of the tunable coupler 130, which causes a relatively large amount of longitudinal coupling (ZZ coupling) between the tunable coupler 130 and the first and second qubits 110 and 120 due to higher energy excitations in the first and second qubits 110 and 120 and tunable coupler 130, which are at similar energies. The longitudinal coupling between the tunable coupler 130 and the first and second qubits 110 and 120 causes a state-dependent AC-Stark shifting of the transition frequencies of the first and second qubits 110 and 120, wherein the Stark shifting of the frequency of a given qubit is a function of, e.g., (i) a coupling strength between the tunable coupler 130 and the given qubit, and (ii) an amount of detuning between the operating frequency of the coupler circuitry and the operating frequency given qubit. In certain instances, the coupler-mediated ZZ interaction provides a way to entangle two different qubits and create, e.g., a CPHASE gate, because a state-dependent shift in qubit frequency can be made equivalent to a state-dependent phase-shift. ZZ interactions are sometimes referred to as longitudinal coupling or denoted as chi or 2-chi coupling.

Further, in some embodiments, the qubit readout lines 112 and 122 are coupled to the first and second qubits 110 and 120, respectively, using known techniques. In some embodiments, the qubit readout lines 112 and 122 comprise transmission line readout resonators (e.g., half-wavelength coplanar waveguide resonators) which are configured to have resonant frequencies that are detuned from the respective transition frequencies of the respective first and second qubits 110 and 120. In some embodiments, the first and second qubits 110 and 120 are dispersively coupled to the qubit readout lines 112 and 122 for their state readout. In some embodiments, a dispersive readout operation for reading the quantum state of a given superconducting qubit which is coupled to a given readout resonator, is performed by applying a radio frequency (RF) readout control signal to the given readout resonator, and detecting/processing the readout signal that is reflected out from the given readout resonator. An RF readout control signal that is applied to the given readout resonator has a single frequency tone that is the same or similar to the resonant frequency of the readout resonator, a pulse envelope with a given pulse shape (e.g., gaussian pulse envelope), and given pulse duration. In the dispersive regime of qubit-resonator coupling, the RF readout control signal interacts with the given qubit/resonator system, and the resulting output readout signal which is reflected out from the given readout resonator comprises information (e.g., phase and/or amplitude) that is qubit-state dependent.

In some embodiments, as schematically illustrated in FIG. 1, the qubit drive lines 111 and 121, the coupler drive line 131, and/or the qubit readout lines 112 and 122 are formed at least in part on the respective qubit chips 101 and 102. In other embodiments, the qubit drive lines 111 and 121, the coupler drive line 131, and/or the qubit readout lines 112 and 122 are formed at least in part on the interposer 103 and capacitively and/or magnetically coupled to the respective first and second qubits 110 and 120 on the first and second qubit chips 101 and 102.

While FIG. 1 schematically illustrates a single inter-chip qubit-coupler-qubit quantum system between the first and second qubit chips 101 and 102 for ease of illustration and explanation, it is to be understood that the first and second qubit chips 101 and 102 can have multiple inter-chip qubit-coupler-qubit quantum systems disposed at the edges E1 and E2 of the first and second qubit chips 101 and 102, and that the interposer can have multiple instances of the differential coupling components 140 to enable inter-chip coupling of multiple qubit-coupler-qubit quantum systems. Moreover, while FIG. 1 schematically illustrates each of the first and second qubit chips 101 and 102 having a single qubit (e.g., the first and second qubit 110 and 120), it is to be understood that the first and second qubit chips 101 and 102 can each have a respective qubit array comprising multiple qubits with adjacent qubits coupled together (intra-chip coupling) using tunable couplers. In this regard, one or more qubits of a first qubit array on the first qubit chip 101 (which are disposed in proximity to the edge E1 of the first qubit chip 101) can be inter-chip coupled to one or more corresponding qubits of a second qubit array on the second qubit chip 102 (which are disposed in proximity to the edge E2 of the second qubit chip 102) using inter-chip coupling components and techniques as discussed herein.

Moreover, while FIG. 1 shows only first and second qubit chips 101 and 102 for ease of illustration and discussion, it is to be understood that the package structure 100 (and other exemplary package structures as discussed herein) can have three or more qubits chips that are disposed in a linear or two-dimensional array, with differential coupling between adjacent qubit chips. For example, the package structure 100 of FIG. 1 can have third qubit chip that is disposed adjacent to the second qubit chip 102, with the second and third qubit chips coupled by second differential coupling bus. Further, the third qubit chip may comprise a third qubit which is coupled (via the second differential coupling bus) to a fourth qubit and a tunable coupler on the second qubit chip 102.

Moreover, while the first and second qubits 110 and 120 are generically illustrated in FIG. 1, it is to be understood that the first and second qubits 110 and 120 can be implemented using any type of superconducting qubit architecture. For example, the first and second qubits 110 and 120 can be implemented using superconducting transmon qubits, fluxonium qubits, multimode qubits (e.g., two-junction qubits, or tunable coupling qubits), and other suitable types of superconducting qubits. The first and second qubits 110 and 120 can be fixed-frequency qubits, or tunable frequency qubits. Moreover, in some embodiments, the tunable coupler 130 is implemented using a frequency tunable qubit, which operates as a bus coupler but does not encode quantum information.

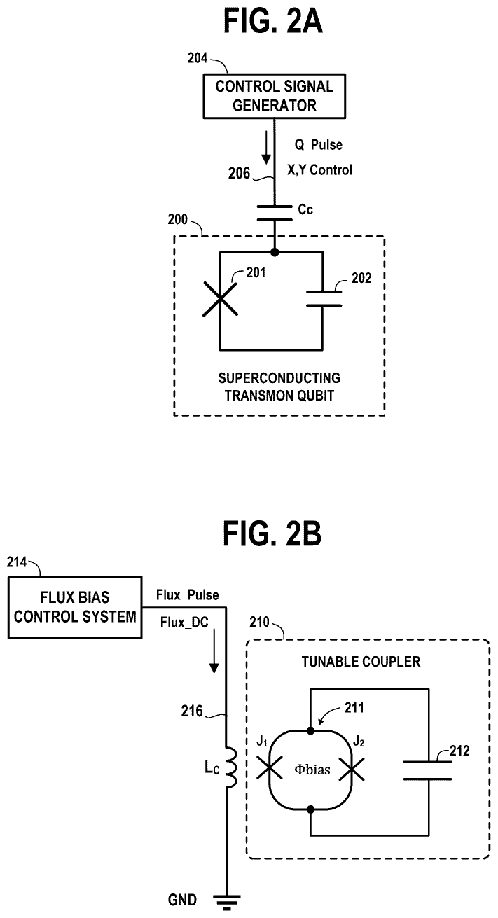

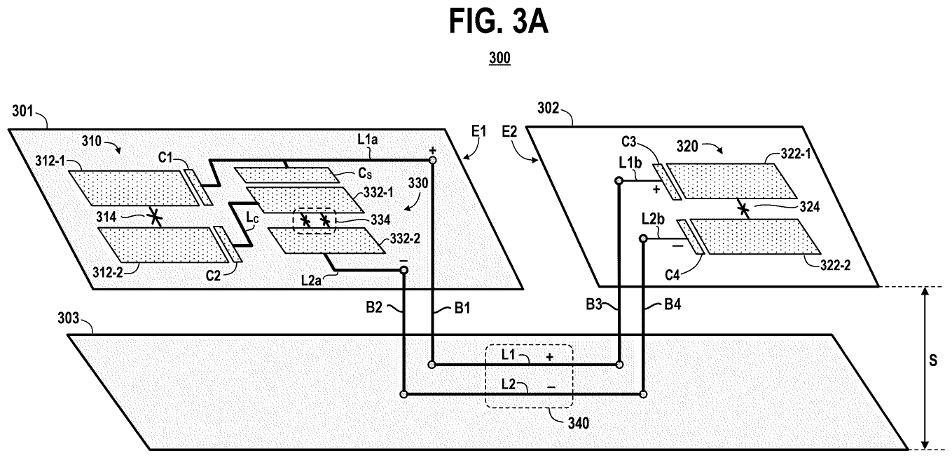

FIG. 2A schematically illustrates an exemplary superconducting qubit which can be implemented on a qubit chip of the package structure of FIG. 1, according to an exemplary embodiment of the disclosure. In particular, FIG. 2A schematically illustrates a superconducting qubit 200 which comprises a fixed frequency transmon qubit that comprises a superconducting Josephson junction 201 connected in parallel with a capacitor 202. The Josephson junction 201 functions as a non-linear inductor which, when shunted with the capacitor 202, forms an anharmonic LC oscillator with individually addressable energy levels (e.g., two lowest energy levels corresponding to computational basis states including the ground state |0> and the first excited state |1>). In some embodiments, the first and second qubits 110 and 120 in FIG. 1 can be implement using the superconducting qubit 200 of FIG. 2A (e.g., fixed-frequency transmon qubit), or other types of superconducting qubits such as fluxonium qubits, etc.

As further shown in FIG. 2A, a control signal generator 204 is configured to generate a given microwave pulse (denoted Q_Pulse) to drive single qubit X- and Y-rotation gates on the superconducting qubit 200. The microwave pulse, Q_Pulse, is applied to a qubit drive line 206 which is capacitively coupled to the superconducting qubit 200 via a coupling capacitor Cc. In some embodiments, the control signal generator 204 comprises a multi-channel arbitrary waveform generator (AWG) which is configured to generate control signals to control the operation (e.g., state change and readout) of superconducting qubit 200. To implement an X gate and/or Y gates, a suitable microwave control pulse Q_Pulse is generated which has a center frequency (tone) near or equal to the transition frequency of the superconducting qubit 200, and suitably shaped pulse envelope (e.g., a gaussian pulse envelope), that is calibrated to drive f₀₁ transitions of the superconducting qubit 200, while suppressing f₁₂ and higher transitions. The microwave control pulse Q_Pulse is configured to change the state of the superconducting qubit 200 by rotating the state of the given qubit about an axis of the Bloch sphere, wherein such rotations include X-axis rotations, Y-axis rotations, and/or rotations about any axis in the X-Y plane of the Bloch sphere, wherein the axis of rotation about a given axis of the Bloch sphere and the amount (angle) of such rotation are based, respectively, on the phase of the microwave control signal, and the amplitude and duration of the microwave control signal.

In addition, the control signal generator 204 is configured to generate a readout control signal which comprises an RF control pulse with a center frequency that corresponds to the resonant frequency of a readout resonator that is coupled to the superconducting qubit 200. As noted above, a readout resonator that is coupled to a given qubit comprises, e.g., half-wavelength coplanar waveguide resonator, which is utilized to readout the quantum state of the given qubit using, e.g., dispersive readout systems and techniques, which are well-known to those of ordinary skill in the art. For ease of illustration, FIG. 2A does not illustrate the readout resonator or readout signal chain which transmits the readout signal to readout processing circuitry.

Next, FIG. 2B schematically illustrates an exemplary tunable coupler which can be implemented on a qubit chip of the package structure of FIG. 1, according to an exemplary embodiment of the disclosure. In particular, FIG. 2B schematically illustrates a tunable coupler 210 which comprises a flux-tunable transmon qubit coupler having a flux-tunable operating frequency. The tunable coupler 210 is similar in structure to the superconducting qubit 200 of FIG. 2A, except that the transmon qubit coupler is configured to be flux-tunable by implementing DC SQUID 211 in place of the single Josephson junction 201. The DC SQUID 211 comprises a first Josephson junction J1 and a second Josephson junction J2, which are connected in parallel to form a superconducting loop (referred to as SQUID loop) through which an external magnetic flux bias Φ_{Bias} is threaded to adjust the frequency of the tunable coupler 210 to control the interaction (e.g., facilitate exchange interaction or suppress crosstalk) between adjacent qubits.

As further shown in FIG. 2B, a flux bias control system 214 is configured to generate flux bias control signals, denoted Flux_DC and Flux_Pulse, to tune the operating frequency of the tunable coupler 210. The flux bias control signals Flux_DC and Flux_Pulse are applied to a coupler drive line 216, and magnetically coupled to the DC SQUID 211 via a coupling inductor Lc. The Flux_DC control signal comprises a DC flux bias signal that is magnetically coupled to the DC SQUID 211 to generate a static magnetic field that threads through the superconducting loop of the DC SQUID 211. The static magnetic field modulates the critical current, and thus, the Josephson energy of the DC SQUID 211 in a manner which causes the tunable coupler 210 to be maintained in an OFF state which, as noted above, suppresses exchange interactions between adjacent superconducting qubits.

On the other hand, a flux bias control signal (Flux_Pulse) can be generated to temporarily place the tunable coupler 210 into an ON state, when needed, to modulate an exchange interaction between the first and second superconducting qubits. In this instance, the flux bias control signal (Flux_Pulse) is combined with the DC flux bias signal (Flux_DC) to dynamically increase the flux bias current through the coupling inductor Lc and thereby change the magnitude of the flux bias Φ_{Bias} that is threaded through the superconducting loop of the DC SQUID 211 for purposes of, e.g., placing the tunable coupler 210 into an ON state for a duration of the flux bias control signal (Flux_Pulse) to facilitate a coupler-mediated entanglement gate between a first qubit and a second qubit.

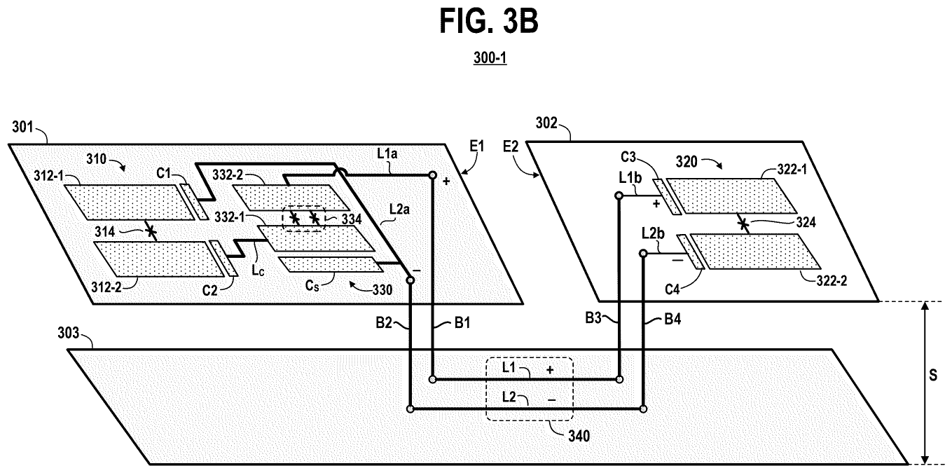

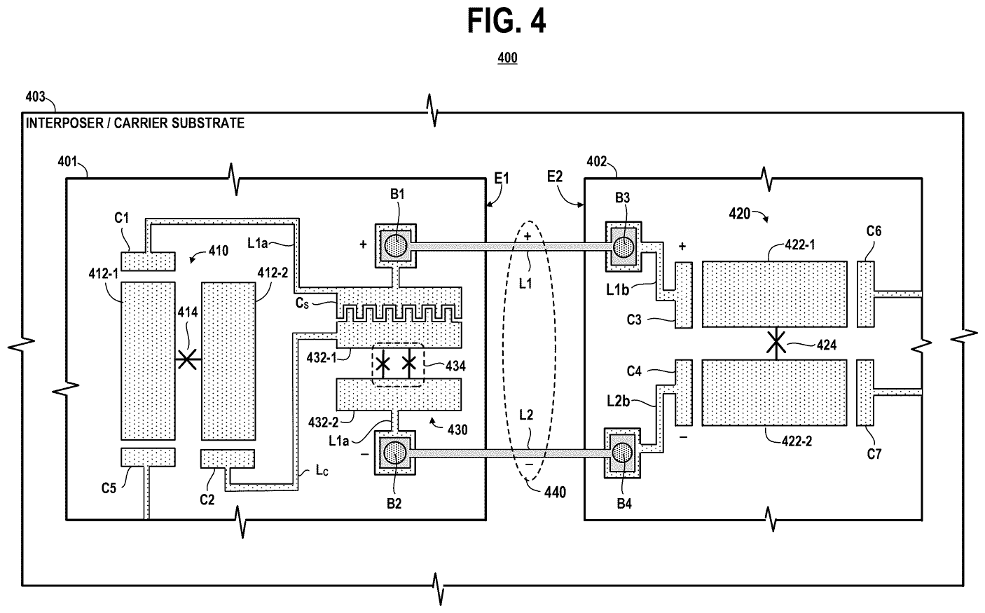

The package structure 100 of FIG. 1 can be implemented using various architectures and implementations of superconducting qubits, tunable couplers, and inter-chip coupling components. For example, FIG. 3A is a schematic perspective view of a package structure comprising quantum bit chips and a differential coupling bus for coupling the quantum bit chips. In particular, FIG. 3A schematically illustrates a package structure 300 comprising a first quantum bit chip 301 (or first qubit chip 301), a second quantum bit chip 302 (or second qubit chip 302), and an interposer 303. The first and second qubit chips 301 and 302 have frontside surfaces with patterned metallization and circuitry which defines qubits, tunable couplers, transmission lines, etc. The first and second qubit chips 301 and 302 are flip-chip bonded via solder bump connections to a frontside surface of the interposer 303, such that the first and second qubit chips 301 and 302 are (i) horizontally separated by a small gap between respective edges E1 and E2 of the first and second qubit chips 301 and 302, and (ii) vertically separated from the interposer 303 by a vertical spacing S that defines a vacuum gap between the frontside surface of the interposer 303 and the frontside surfaces of the first and second qubit chips 301 and 302. The vertical spacing S is fixed by the height of the bump connections post-bonding, wherein the vertical spacing S can be in a range of, e.g., 1 micron to 5 microns.

For example, FIG. 3A schematically illustrates bump connections B1 and B2 (e.g., indium solder bump connections) between the first qubit chip 301 and the interposer 303, and bump connections B3 and B4 between the second qubit chip 302 and the interposer 303. However, for ease of illustration, FIG. 3A does not show ground planes on the first and second qubit chips 301 and 302 or the interposer 303, or bump connections that would be used for, e.g., bonding the ground planes of the frontside surfaces of the first and second qubit chips 301 and 302 to the ground planes on the frontside surface of the interposer 303, or used for making other direct (galvanic) connections between the interposer 303 and other components on the first and second qubit chips 301 and 302.

The first qubit chip 301 comprises a first qubit 310 and a tunable coupler 330, which are formed on the frontside surface of the first qubit chip 301 in proximity to the edge E1 of the first qubit chip 301. In particular, FIG. 3A schematically shows an exemplary planar circuit configuration of the first qubit 310 which comprises a transmon qubit comprising a first superconducting pad 312-1, a second superconducting pad 312-2, and a Josephson junction 314 that is coupled to, and disposed between, the first and second superconducting pads 312-1 and 312-2. The first and second superconducting pads 312-1 and 312-2 comprise first and second electrodes of a coplanar parallel-plate capacitor of the first qubit 310, which is coupled in parallel with the Josephson junction 314. The first superconducting pad 312-1 is disposed adjacent to a coupling capacitor C1 to implement a coplanar parallel plate capacitor with a given coupling capacitance. The second superconducting pad 312-2 is disposed adjacent to a coupling capacitor C2 to implement a coplanar parallel plate capacitor with a given coupling capacitance. The coupling capacitors C1 and C2 are configured to capacitively couple the first qubit 310 to a differential coupling bus of the package structure 300.

Further, the tunable coupler 330 comprises a tunable transmon qubit coupler (similar to the tunable coupler 210, FIG. 2B), wherein the tunable coupler 330 comprises a first superconducting pad 332-1 and a second superconducting pad 332-2 (which form a parallel plate capacitor), and a SQUID 334 comprising two Josephson junctions that are coupled to, and disposed between, the first and second superconducting pads 332-1 and 332-2. The first superconducting pad 332-1 of the tunable coupler 330 is disposed adjacent to a coupling capacitor electrode C_{S} (alternatively referred to herein as shunting capacitor electrode C_{S}). The first superconducting pad 332-1 of the tunable coupler 330 is connected to the coupling capacitor C2 by a transmission line L_{C}.

The second qubit chip 302 comprises a second qubit 320 which is formed on the frontside surface of the second qubit chip 302 in proximity to the edge E2 of the second qubit chip 302. The second qubit 320 comprises a transmon qubit comprising a first superconducting pad 322-1 and a second superconducting pad 322-2 (which form a parallel plate capacitor), and a Josephson junction 324 that is coupled to, and between, the first and second superconducting pads 322-1 and 322-2. The first superconducting pad 322-1 is disposed adjacent to a coupling capacitor C3 to implement a coplanar parallel plate capacitor with a given coupling capacitance. The second superconducting pad 322-2 is disposed adjacent to a coupling capacitor C4 to implement a coplanar parallel plate capacitor with a given coupling capacitance. The coupling capacitors C3 and C4 are configured to capacitively couple the second qubit 320 to the differential coupling bus of the package structure 300.

The interposer 303 comprises differential transmission lines 340 which include a first transmission line L1 and a second transmission line L2. In an exemplary embodiment, the first and second transmission lines L1 and L2 are planar coplanar waveguide (CPW) transmission lines, which are formed on the frontside surface of the interposer 303. As schematically illustrated in FIG. 3A, the first transmission line L1 is coupled to and between bonding sites of the bump connections B1 and B3 on the interposer 303, and the second transmission line L2 is coupled to and between bonding sites of the bump connections B2 and B4 on the interposer 303.

As further schematically shown in FIG. 3A, the bump connection B1 is connected to a first transmission line L1a on the frontside surface of the first qubit chip 301. The first transmission line L1a is connected to the coupling capacitor C1 and the shunting capacitor electrode C_{S}. Further, the bump connection B2 is connected to a second transmission line L2a on the frontside surface of the first qubit chip 301, and the second transmission line L2a is connected to the second superconducting pad 332-2 of the tunable coupler 330.

The exemplary package structure 300 comprises a differential coupling bus that is configured to provide galvanic and differential coupling of the first qubit chip 301 and the second qubit chip 302 via, e.g., the bump connections B1, B2, B3, and B4, and the differential transmission lines 340, wherein the differential coupling framework of the package structure 300 serves to reduce or eliminate any adverse effects of external fields or other sources of noise. For example, the differential coupling bus is configured to suppress common mode noise between the first and second qubit chips 301 and 302 from adversely affecting the transmission of RF energy between the first and second qubits 310 and 320 on the separate first and second qubit chips 301 and 302. As noted above, with the exemplary package structure 300, the gap between the edges E1 and E2 of the first and second qubit chips 301 and 302 can have package modes (e.g., long range modes) that can add noise into the transmission lines, e.g., the noise from the interactions of the package modes typically interacts with a common mode of exposed transmission lines. However, the differential coupling bus configuration provides good immunity to such package modes and serves to significantly reduce or otherwise eliminate the coupling of package mode noise to the first and second qubits 310 and 320.

More specifically, the exemplary package structure 300 of FIG. 3A comprises a differential coupling bus that is configured to differentially couple the first qubit 310 and the second qubit 320 by operation of the tunable coupler 330. In the exemplary embodiment, the differential coupling bus comprises a first electrical path and a second electrical path which are capacitively coupled to the first and second qubits 310 and 320. Essentially, the first electrical path (of the differential coupling bus) comprises a series connection of the first transmission line L1a (on the first qubit chip 301), the bump connection B1, the first transmission line L1 of the differential transmission lines 340 (on the interposer 303), the bump connection B3, and the first transmission line L1b (on the second qubit chip 302). The second electrical path (of the differential coupling bus) comprises a series connection of the transmission line Lc (on the first qubit chip 301), the tunable coupler 330, the second transmission line L2a (on the first qubit chip 301), the bump connection B2, the second transmission line L2 of the differential transmission lines 340 (on the interposer 303), the bump connection B4, and the second transmission line L2b (on the second qubit chip 302).

The tunable coupler 330 is implemented as a component of the differential coupling bus to add a resonant mode which controls the interaction between the first qubit 310 and the second qubit 320. In an exemplary embodiment, the tunable coupler 330 is configured to operate in a first state (e.g., OFF state) in which the frequency of the tunable coupler 330 is far detuned from the transition frequencies of the first and second qubits 310 and 320, wherein the frequency of the tunable coupler 330 (in the OFF state) is much lower than the transition frequencies of the first and second qubits 310 and 320. In the OFF state, the tunable coupler 330 essentially serves to decouple the first and second qubits 310 and 320 by suppressing interaction (static or otherwise) between the first and second qubits 310 and 320. With the differential configuration, when tunable coupler 330 is tuned in the OFF state, the differential coupling configuration enables the tunable coupler 330 to cancel the coupling between the first and second qubits 310 and 320, resulting in substantially a zero net coupling between the first and second qubits 310 and 320. On the other hand, the tunable coupler 330 is configured to operate in a second state (e.g., ON state) in which the frequency of the tunable coupler 330 is tuned closer to the transition frequencies of the first and second qubits 310 and 320, which serves to couple the first and second qubits 310 and 320 by increasing the coupling and interaction between the first and second qubits 310 and 320.

In the exemplary configuration shown in FIG. 3A, in the second electrical path of the differential coupling bus, the tunable coupler 330 provides a DC connection between the bump connection B2 and the coupling capacitor C2 of the first qubit 310. On the other hand, the tunable coupler 330 adds an RF mode which has a polarity that is opposite to the polarity of the direct capacitive coupling, which allows the qubit-qubit coupling to be turned ON and OFF.

As noted above, the differential coupling between the first and second qubits 310 and 320 serves to suppress common mode noise that may be present on the differential transmission lines L1 and L2 of the differential transmission lines 340 due to the transmission lines L1 and L2 being exposed to microwave modes of the package structure between the first and second qubit chips 301 and 302. In addition, the differential coupling scheme in FIG. 3A further provides some level of common mode suppression for the tunable coupler 330 to prevent the common mode noise from unduly affecting the tunable coupler 330.

In particular, as schematically illustrated in FIG. 3A, the shunting capacitor electrode C_{S} is galvanically connected to the first transmission line L1a (as well as the coupling capacitor C1 and bump connection B1). In this regard, the first electrical path of the differential coupling bus is capacitively coupled to the first superconducting pad 332-1 of the tunable coupler 330 via a shunting capacitance between the shunting capacitor electrode C_{S} and the first superconducting pad 332-1, wherein the shunting capacitor electrode C_{S} and the first superconducting pad 332-1 essentially form a coplanar capacitor which provides the shunting capacitance between the tunable coupler 330 and the first electrical path of the differential coupling bus. In this configuration, the shunting capacitance (via implementation of the shunt capacitor electrode C_{S}) serves to provide some level of noise immunity for the tunable coupler 330, and thereby suppresses common mode noise from affecting the tunable coupler 330.

FIG. 3B is a schematic perspective view of a package structure comprising quantum bit chips and a differential coupling bus for coupling the quantum bit chips. In particular, FIG. 3B schematically illustrates a package structure 300-1 which is similar in architecture and operation as the package structure 300 of FIG. 3A, except that that polarization of the differential coupling bus with regard to the first qubit 310 is flipped. In particular, similar to the exemplary package structure 300 of FIG. 3A, the package structure 300-1 of FIG. 3B comprises a differential coupling bus that is configured to differentially couple the first qubit 301 and the second qubit 302 by operation of the tunable coupler 330.

The differential coupling bus comprises a first electrical path and a second electrical path which differentially couple the first and second qubits 301 and 302. In the exemplary embodiment of FIG. 3B, the differential coupling bus comprises a first electrical path and a second electrical path which are capacitively coupled to the first and second qubits 310 and 320. However, the first electrical path (of the differential coupling bus) comprises a series connection of the transmission line L_{C} (on the first qubit chip 301), the tunable coupler 330, the first transmission line L1a (on the first qubit chip 301), the bump connection B1, the first transmission line L1 of the differential transmission lines 340 (on the interposer 303), the bump connection B3, and the first transmission line L1b (on the second qubit chip 302). The second electrical path (of the differential coupling bus) comprises a series connection of the second transmission line L2a (on the first qubit chip 301), the bump connection B2, the second transmission line L2 of the differential transmission lines 340 (on the interposer 303), the bump connection B4, and the second transmission line L2b (on the second qubit chip 302).

Moreover, as schematically illustrated in FIG. 3B, the shunting capacitor electrode C_{S} is galvanically connected to the second transmission line L2a. In this regard, the second electrical path of the differential coupling bus is capacitively coupled to the first superconducting pad 332-1 of the tunable coupler 330 via a shunting capacitance between the shunting capacitor electrode C_{S} and the first superconducting pad 332-1 of the tunable coupler 330, wherein the shunting capacitor electrode C_{S} and the first superconducting pad 332-1 essentially form a coplanar capacitor which provides the shunting capacitance between the tunable coupler 330 and the second electrical path of the differential coupling bus. As noted above, in this configuration, the shunting capacitance (via implementation of the shunt capacitor electrode C_{S}) serves to provide some level of noise immunity for the tunable coupler 330, and thereby suppress common mode noise from affecting the tunable coupler 330.

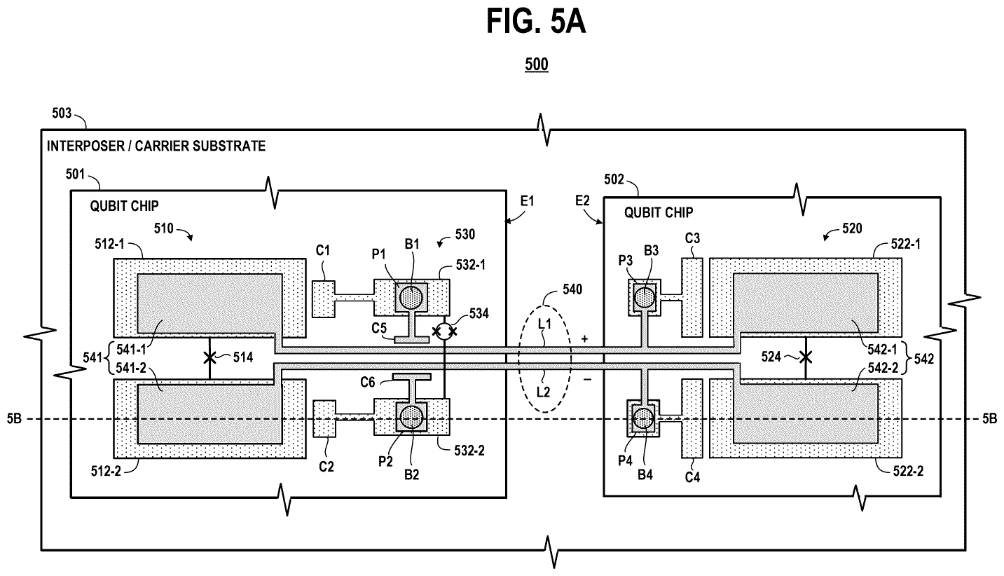

FIG. 4 is a schematic plan view of a package structure comprising quantum bit chips and a differential coupling bus for coupling the quantum bit chips, according to another exemplary embodiment of the disclosure. In particular, FIG. 4 schematically illustrates a package structure 400 which has an architecture and that is similar to the package structure 300 of FIG. 3A. For example, the package structure 400 comprises a first qubit chip 401, a second qubit chip 402, and an interposer 403, wherein the first and second qubit chips 401 and 402 are flip-chip bonded to the interposer 403 using bump connections (e.g., bump connections B1, B2, B3, B4).

The first qubit chip 401 comprises a first qubit 410 and a tunable coupler 430, which are formed on the frontside surface of the first qubit chip 401 in proximity to the edge E1 of the first qubit chip 401. FIG. 4 schematically illustrates an exemplary planar circuit configuration of the first qubit 410 which comprises a transmon qubit comprising a first superconducting pad 412-1, a second superconducting pad 412-2, and a Josephson junction 414. The first superconducting pad 412-1 is disposed adjacent to a coupling capacitor C1 to implement a coplanar parallel plate capacitor with a given coupling capacitance. The second superconducting pad 412-2 is disposed adjacent to a coupling capacitor C2 to implement a coplanar parallel plate capacitor with a given coupling capacitance. The coupling capacitors C1 and C2 are configured to capacitively couple the first qubit 410 to the differential coupling bus of the package structure 400.

The second qubit chip 402 comprises a second qubit 420 which is formed on the frontside surface of the second qubit chip 402 in proximity to the edge E2 of the second qubit chip 402. The second qubit 420 comprises a transmon qubit comprising a first superconducting pad 422-1, a second superconducting pad 422-2, and a Josephson junction 424 that is coupled to, and between, the first and second superconducting pads 422-1 and 422-2. The first superconducting pad 422-1 is disposed adjacent to a coupling capacitor C3 to implement a coplanar parallel plate capacitor with a given coupling capacitance. The second superconducting pad 422-2 is disposed adjacent to a coupling capacitor C4 to implement a coplanar parallel plate capacitor with a given coupling capacitance. The coupling capacitors C3 and C4 are configured to capacitively couple the second qubit 420 to the differential coupling bus of the package structure 400.

The interposer 403 comprises differential transmission lines 440 which include a first transmission line L1 and a second transmission line L2, which comprise, e.g., CPW transmission lines formed on the frontside surface of the interposer 403. As schematically illustrated in FIG. 4, the first transmission line L1 is coupled to and between bonding sites of the bump connections B1 and B3 on the interposer 403, and the second transmission line L2 is coupled to and between bonding sites of the bump connections B2 and B4 on the interposer 403.

Further, the tunable coupler 430 (e.g., a flux-tunable qubit coupler) comprises a first superconducting pad 432-1, a second superconducting pad 432-2 (which form a parallel plate capacitor), and a SQUID 434. The first superconducting pad 432-1 of the tunable coupler 430 is disposed adjacent to a shunting capacitor electrode C_{S}. The first superconducting pad 432-1 of the tunable coupler 430 is connected to the coupling capacitor C2 by a transmission line L_{C}. The modes of operation of the tunable coupler 430 and the exemplary package structure 400 of FIG. 4 are the same or similar to the operating modes of the package structure 300 discussed above in conjunction with FIG. 3A, the details of which will not be repeated.

However, as schematically illustrated in FIG. 4, the shunting capacitor electrode C_{S} and the first superconducting pad 432-1 of the tunable coupler 430 comprise a coplanar capacitor which comprises an interdigitated coplanar capacitor architecture, in which the shunting capacitor electrode C_{S} and the first superconducting pad 432-1 are patterned to include corresponding opposing patterns of fingers and grooves that are interdigitated (or interlaced) to provide increased direct coupling capacitance between the first electrical path (of the differential coupling bus) and the tunable coupler 430 which, in the exemplary embodiment of FIG. 4, is serially connected in the second electrical path of the differential coupling bus, as explained above. The interdigitated capacitor design renders tunable coupler 430 relatively insensitive to minor change of capacitance when varying the line length between the qubits.

FIG. 4 further illustrates an additional capacitor electrode C5 disposed adjacent to the first superconducting pad 412-1 of the first qubit 410, and capacitor electrodes C6, and C7 that are disposed adjacent to the first superconducting pad 422-1 and the second superconducting pad 422-2, respectively, of the second qubit 420. In some embodiments, the additional capacitor electrodes C5, C6, and C7, are utilized for additional qubit-qubit connectivity when tiling the structure into a lattice arrangement of qubits.

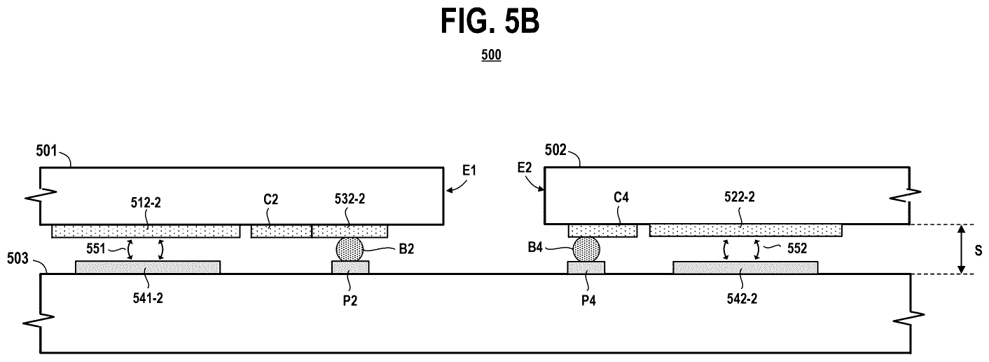

FIGS. 5A and 5B schematically illustrate a package structure comprising quantum bit chips and a differential coupling bus for coupling the quantum bit chips, according to another exemplary embodiment of the disclosure. More specifically, FIG. 5A is a schematic top plan view of a package structure 500, and FIG. 5B is a schematic cross-sectional side view of the package structure 500 along line 5B-5B in FIG. 5A. As shown FIGS. 5A and 5B, the package structure 500 comprises a first qubit chip 501, a second qubit chip 502, and an interposer 503, wherein the first and second qubit chips 501 and 502 are flip-chip bonded to the interposer 503 using bump connections (e.g., bump connections B1, B2, B3, B4).

The first qubit chip 501 comprises a first qubit 510 and a tunable coupler 530, which are formed on the frontside surface of the first qubit chip 501 in proximity to the edge E1 of the first qubit chip 501. The second qubit chip 502 comprises a second qubit 520 which is formed on the frontside surface of the second qubit chip 502 in proximity to the edge E2 of the second qubit chip 502. Similar to the exemplary embodiments discussed above, FIG. 5A schematically illustrates an exemplary planar circuit configuration of the first qubit 510 which comprises a first superconducting pad 512-1, a second superconducting pad 512-2, and a Josephson junction 514. The first superconducting pad 512-1 is disposed adjacent to a coupling capacitor C1 to implement a coplanar parallel plate capacitor with a given coupling capacitance. The second superconducting pad 512-2 is disposed adjacent to a coupling capacitor C2 to implement a coplanar parallel plate capacitor with a given coupling capacitance.

Similarly, the second qubit 520 comprises a first superconducting pad 522-1, a second superconducting pad 522-2, and a Josephson junction 524. The first superconducting pad 522-1 is disposed adjacent to a coupling capacitor C3 to implement a coplanar parallel plate capacitor with a given coupling capacitance. The second superconducting pad 522-2 is disposed adjacent to a coupling capacitor C4 to implement a coplanar parallel plate capacitor with a given coupling capacitance.

The tunable coupler 530 (e.g., a flux-tunable transmon qubit coupler) comprises a first superconducting pad 532-1, a second superconducting pad 532-2 (which form a parallel plate capacitor), and a SQUID 534. The first superconducting pad 532-1 of the tunable coupler 530 is directly connected to the coupling capacitor C1 to enable capacitive coupling between the first superconducting pad 532-1 of the tunable coupler 530 and the first superconducting pad 512-1 of the first qubit 510. Similarly, the superconducting pad 532-2 of the tunable coupler 530 is directly connected to the coupling capacitor C2 to enable capacitive coupling between the second superconducting pad 532-2 of the tunable coupler 530 and the second superconducting pad 512-2 of the first qubit 510.

The interposer 503 comprises differential transmission lines 540 which include a first transmission line L1 and a second transmission line L2. In some embodiments, the first and second transmission lines L1 and L2 comprise CPW transmission lines formed on the frontside surface of the interposer 503. The interposer 503 further comprises a first differential coupling capacitor 541, a second differential coupling capacitor 542, bond pads P1, P2, P3, and P4, and coupling capacitor pads C5 and C6, which comprise patterned metallization on the frontside surface of the interposer 503.

The first differential coupling capacitor 541 comprises a first capacitor pad 541-1 and a second capacitor pad 541-2. The first capacitor pad 541-1 is disposed under and aligned to the first superconducting pad 512-1 of the first qubit 510, and the second capacitor pad 541-2 is disposed under and aligned to the second superconducting pad 512-2 of the first qubit 510. In addition, the first capacitor pad 541-1 is connected to the first transmission line L1, and the second capacitor pad 541-2 is connected to the second transmission line L2. In this configuration, the first differential coupling capacitor 541 and the first and second superconducting pads 512-1 and 512-2 of the first qubit 510 are configured to implement a vacuum gap capacitor structure which provides a non-galvanic connection between the first qubit 510 (on the first qubit chip 501) and the differential transmission lines 540 (on the interposer 503).

Similarly, the second differential coupling capacitor 542 comprises a first capacitor pad 542-1 and a second capacitor pad 542-2. The first capacitor pad 542-1 is disposed under and aligned to the first superconducting pad 522-1 of the second qubit 520, and the second capacitor pad 542-2 is disposed under and aligned to the second superconducting pad 522-2 of the second qubit 520. In addition, the first capacitor pad 542-1 is connected to the first transmission line L1, and the second capacitor pad 541-2 is connected to the second transmission line L2. In this configuration, the second differential coupling capacitor 542 and the superconducting pads 522-1 and 522-2 of the second qubit 520 are configured to implement a vacuum gap capacitor structure which provides a non-galvanic connection between the second qubit 520 (on the second qubit chip 502) and the differential transmission lines 540 (on the interposer 503).

Collectively, the first and second differential coupling capacitors 541 and 542, and the differential transmission lines 540 implement a differential coupling bus that is configured to differentially couple the first and second qubits 510 and 520, and suppress common mode noise between the first and second qubit chips 501 and 502, and prevent package modes from adversely affecting the transmission of RF energy between the first and second qubits 510 and 520 on the separate first and second qubit chips 501 and 502.

In some embodiments, it is desirable to increase the non-galvanic (capacitive) coupling between the second qubit 520 and the differential coupling bus (e.g., the differential transmission lines 540). In this regard, to increase the capacitive coupling between the second qubit 520 and the differential transmission lines 540, additional galvanic connections may be implemented via the bump connections B3 and B4 to galvanically connect the respective coupling capacitors C3 and C4 to the respective first and second transmission lines L1 and L2. In this instance, the first superconducting pad 522-1 of the second qubit 520 is capacitively coupled to the coupling capacitor C3, wherein the coupling capacitor C3 is galvanically connected to the first transmission line L1 via the bump connection B3 and the bond pad P3 on the interposer 503 which is connected to the first transmission line L1. Similarly, the second superconducting pad 522-2 of the second qubit 520 is capacitively coupled to the coupling capacitor C4, wherein the coupling capacitor C4 is galvanically connected to the second transmission line L2 via the bump connection B4 and the bond pad P4 on the interposer 503 which is connected to the second transmission line L2.

In the exemplary package structure 500, the tunable coupler 530 is capacitively coupled to the first and electrical paths of the differential coupling bus between the first and second qubits 510 and 520. For example, as schematically illustrated in FIG. 5A, the first superconducting pad 532-1 of the tunable coupler 530 serves as a bond pad for the bump connection B1. The bump connection B1 provides galvanic connection to the bond pad P1 on the interposer 503, and the bond pad P1 is connected to the coupling capacitor pad C5. The coupling capacitor pad C5 is disposed adjacent to a portion of the first transmission line L1. In this configuration, the first superconducting pad 532-1 of the tunable coupler 530 is capacitively coupled to the first transmission line L1.

Similarly, as schematically shown in FIGS. 5A and 5B, the second superconducting pad 532-2 of the tunable coupler 530 serves as a bond pad for the bump connection B2. The bump connection B2 provides galvanic connection to the bond pad P2 on the interposer 503, and the bond pad P2 is connected to the coupling capacitor pad C6. The coupling capacitor pad C6 is disposed adjacent to a portion of the second transmission line L2. In this configuration, the second superconducting pad 532-2 of the tunable coupler 530 is capacitively coupled to the second transmission line L2.

In addition, the first capacitor pad 541-1 is connected to the first transmission line L1, and the second capacitor pad 541-2 is connected to the second transmission line L2. In this configuration, the first differential coupling capacitor 541 and the first and second superconducting pads 512-1 and 512-2 of the first qubit 510 are configured to implement a vacuum gap capacitor structure which provides a non-galvanic connection between the first qubit 510 (on the first qubit chip 501) and the differential transmission lines 540 (on the interposer 503).

As schematically shown in FIG. 5B, the second capacitor pad 541-2 of the first differential coupling capacitor 541 is disposed under and aligned to the second superconducting pad 512-2 of the first qubit 510. This exemplary configuration enables a non-galvanic capacitive coupling (as schematically illustrated by curved arrows 551) between the second capacitor pad 541-2 of the first differential coupling capacitor 541, and the second superconducting pad 512-2 of the first qubit 510. Similarly, FIG. 5B schematically illustrates that the second capacitor pad 542-2 of the second differential coupling capacitor 542 is disposed under and aligned to the second superconducting pad 522-2 of the second qubit 520. This exemplary configuration enables a non-galvanic capacitive coupling (as schematically illustrated by curved arrows 552) between the second capacitor pad 542-2 of the second differential coupling capacitor 542, and the second superconducting pad 522-2 of the second qubit 520.

In the exemplary package configuration shown in FIGS. 5A and 5B, the coupling of the tunable coupler 530 to the coupling bus is fully differential, which is to be contrasted with the exemplary package structures 300, 300-1, and 400 as discussed above, where the tunable coupler is serially connected in a first electrical path of a differential coupling bus, and capacitively to a second electrical path of the differential coupling bus via a bypass shunting capacitor (which provides some level of common mode noise immunity). In the exemplary package structure 500, the tunable coupler 530 is fully differential and symmetric, and is thus immune to common mode noise from microwave modes of the package between the qubit chips.

As with the exemplary embodiments discussed above, the tunable coupler 530 is configured to control interactions between the first and second qubits 510 and 520. In one operating state (ON state), the tunable coupler 530 enables coupling and interactions between the first and second qubits 510 and 520 over the differential coupling bus (e.g., the differential transmission lines 540). In another operating state (OFF state), the tunable coupler 530 is configured to cancel the direct capacitive coupling between the first and second qubit 510 and 520.

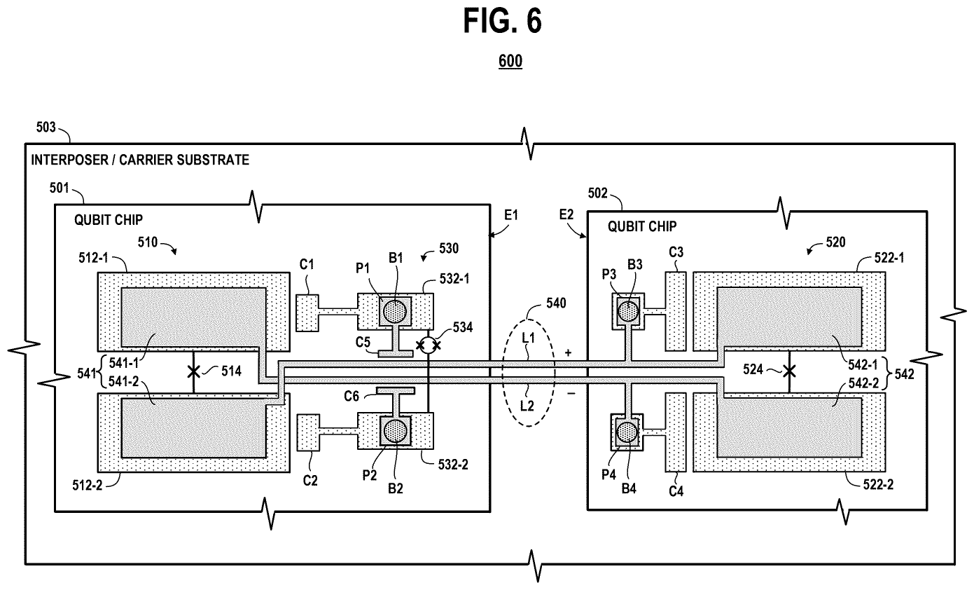

FIG. 6 schematically illustrate a package structure comprising quantum bit chips and a differential coupling bus for coupling the quantum bit chips, according to another exemplary embodiment of the disclosure. More specifically, FIG. 6 is a schematic top plan view of a package structure 600 which is similar to the package structure 500 as shown in FIG. 5A. However, the package structure 600 is configured with an opposite polarity of the capacitive coupling between the first and second qubits over the differential coupling bus. In particular, as shown in FIG. 6, the first capacitor pad 541-1 (of the first differential coupling capacitor 541 is connected to the second transmission line L2 (as opposed to the first transmission line L1 as shown in FIG. 5A), and the second capacitor pad 541-2 (of the first differential coupling capacitor 541) is connected to the first transmission line L1 (as opposed to the second transmission line L1 as shown in FIG. 5A).

It is to be noted that the different package configurations of FIGS. 5A and 6 are implemented depending on a given frequency allocation, e.g., whether the frequency of the tunable coupler 530 is above or below the transition frequencies of the first and second qubits 510 and 520, in order to achieve the desired cancellation when the tunable coupler 530 is in an OFF mode. In the exemplary package structure 500 of FIGS. 5A and 5B, the operating frequency of the tunable coupler 530 is above the transition frequencies of the first and second qubits 510 and 520. On the other hand, in the exemplary package structure 600 of FIG. 6, the operating frequency of the tunable coupler 530 is below the transition frequencies of the first and second qubits 510 and 520.

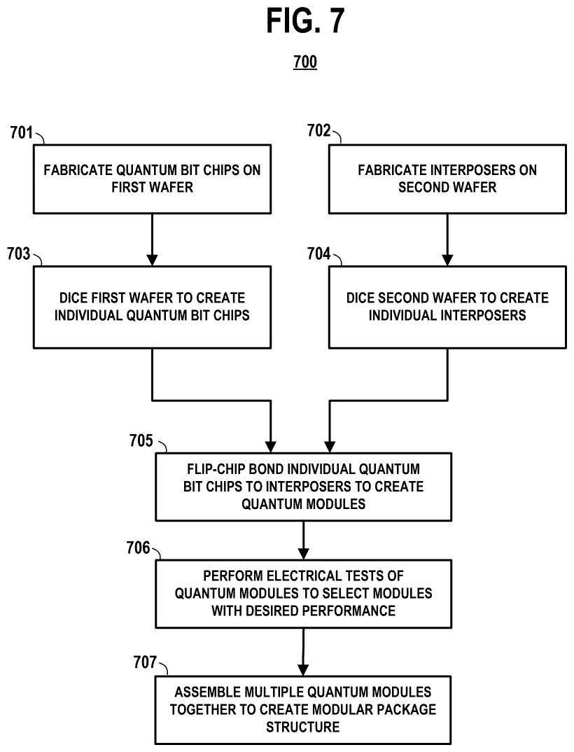

The exemplary modular quantum bit chip package structures discussed herein can be fabricated using state of the art semiconductor fabrication technologies. For example, FIG. 7 illustrates a flow diagram of a method 700 for constructing modular package structures, according to an exemplary embodiment of the disclosure. A plurality of quantum bit chips are fabricated on a first semiconductor wafer (quantum bit chip wafer) (block 701), and a plurality of interposers are fabricated on a second semiconductor wafer (interposer wafer) (block 702). For example, on the quantum bit chip wafer, various quantum bit dies are fabricated, with each quantum bit die comprising various components such as superconducting qubits, tunable couplers, ground planes, signal coplanar waveguides, coupler drive lines, qubit drive lines, readout resonators, coupling capacitor pads, coupling inductors, solder bump bond pads, etc., by lithographically defined patterns of superconducting materials formed on the qubit wafer, which are formed using by, e.g., deposition, optical lithography, etch, and liftoff steps.

In addition, on a given interposer wafer, various interposer die are fabricated to include differential coupling busses and associated components as discussed above, with each interposer die comprising various components such as wiring for signal I/O, ground planes, solder bump bond pads, and package I/O routing and interconnect transmission lines and bond pads, etc., which comprise lithographically defined patterns of superconducting materials formed on the interposer wafer, which are formed using by, e.g., deposition, optical lithography, etch, and liftoff steps. The metallization on the interposer and quantum bit chip wafers can be formed using various types of superconductor materials that are suitable for a given application, including, but not limited to, elementary metals such as niobium (Nb), aluminum (Al), tantalum (Ta), and compounds such as titanium nitride (TiN), niobium nitride (NbN), niobium titanium nitride (NbTiN), etc.

The first semiconductor wafer is diced to create individual quantum bit chips (or individual quantum bit dies) (block 703), and the second semiconductor wafer is diced to create individual interposers (block 704). One or more quantum bit chips are then flip-chip bonded to each of plurality of the interposers to create quantum modules (block 705). In some embodiments, flip-chip bonding a given quantum bit chip to a given interposer is performed by depositing and patterning indium solder bumps onto the given interposer, and then flip-chip bonding the given quantum bit chip to the given interposer using, e.g., a thermo-compression bonding process to create galvanic connections between the quantum bit chip and the interposer.

Next, electrical tests are performed on the individual quantum modules to determine and select modules that function as intended and a desired performance (block 706). The electrical tests can include tests that are performed at room temperature. In addition, the electrical tests can be performed at cryogenic temperatures in a cryostat (e.g., dilution refrigeration system) to test the functionality of the superconducting qubits and other superconducting quantum components on the quantum bit chips. The selected individual quantum modules can then be used to form modular package structures (block 707), wherein a given modular package structure is constructed by assembling two or more individual quantum modules together using suitable methods and structure packaging quantum modules.

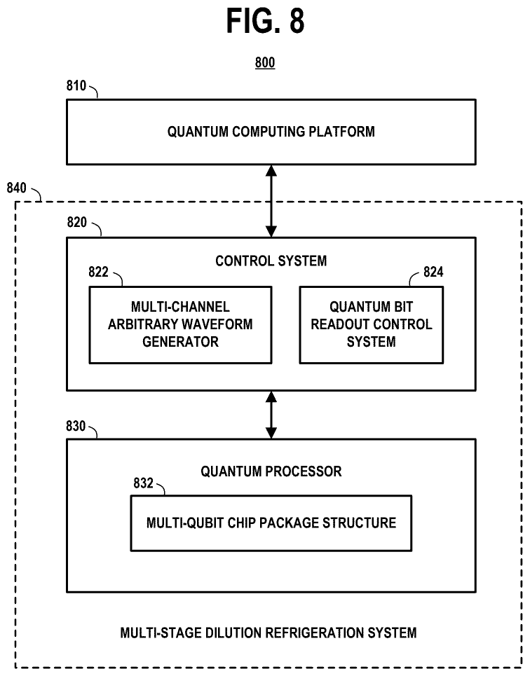

FIG. 8 schematically illustrates a quantum computing system comprising a quantum processor which comprises a modular package structure that is constructed using multiple quantum modules, according to an exemplary embodiment of the disclosure. In particular, FIG. 8 schematically illustrates a quantum computing system 800 which comprises a quantum computing platform 810, a control system 820, and a quantum processor 830. In some embodiments, the control system 820 comprises a multi-channel arbitrary waveform generator (AWG) 822, and a quantum bit readout control system 824. In an exemplary embodiment, the quantum processor 830 comprises at least one multi qubit chip package structure 832, which can be implemented using any one of the exemplary package structures as discussed above, as may be desired for a given application or quantum system configuration.

In some embodiments, the control system 820 and the quantum processor 830 are disposed in a dilution refrigeration system 840 which can generate cryogenic temperatures that are sufficient to operate components of the control system 820 for quantum computing applications. For example, the quantum processor 830 may need to be cooled down to near-absolute zero, e.g., 10-15 millikelvin (mK), to allow the superconducting qubits to exhibit quantum behaviors. In some embodiments, the dilution refrigeration system 840 comprises a multi-stage dilution refrigerator where the components of the control system 820 can be maintained at different cryogenic temperatures, as needed. For example, while the quantum processor 830 may need to be cooled down to, e.g., 10-15 mK, the circuit components of the control system 820 may be operated at cryogenic temperatures greater than 10-15 mK, depending on the configuration of the quantum computing system. In other embodiments, some or all of the components of the control system 820 may comprise electronic components that are disposed and operated in room temperature environment.

In some embodiments, the multi-channel AWG 822 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 822 comprises a plurality of AWG channels, which control respective superconducting qubits on qubit chips within the package structure 832 of the quantum processor 830. In some embodiments, each AWG channel comprises a baseband signal generator, a digital-to-analog converter (DAC) stage, a filter stage, a modulation stage, and an impedance matching network, and a phase-locked loop system to generate local oscillator (LO) signals (e.g., quadrature LO signals LO_I and LO_Q) for the respective modulation stages of the respective AWG channels.

In some embodiments, the multi-channel AWG 822 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control one or more quantum bits that are coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to the filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

In some embodiments, the quantum bit readout control system 824 comprises a microwave pulse signal generator that is configured to applying a microwave tone to a given readout resonator line of a given superconducting qubit to perform a readout operation to readout the state of the given superconducting qubit, as well as circuitry that is configured to process the readout signal generated by the readout resonator line to determine the state of the given superconducting qubit, using techniques known to those of ordinary skill in the art. For example, in some embodiments, a qubit readout line for a given qubit comprise a coplanar waveguide resonator that is configured to have a resonant frequency that is detuned from a transition frequency of the given qubit to enable a dispersive readout operation for reading the quantum state of a given qubit which is coupled to a given readout resonator. A dispersive readout operation involves applying an RF readout control signal (RF_RO) to the given readout resonator, and detecting/processing the readout signal that is reflected out from the given readout resonator. An RF readout control signal that is applied to the given readout resonator has a single frequency tone that is the same or similar to the resonant frequency of the readout resonator, a pulse envelope with a given pulse shape (e.g., gaussian pulse envelope), and given pulse duration. In the dispersive regime of qubit-resonator coupling, the RF readout control signal interacts with the given qubit/resonator system, and the resulting output readout signal which is reflected out from the given readout resonator comprises information (e.g., phase and/or amplitude) that is qubit-state dependent.

The quantum computing platform 810 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), etc. In addition, the quantum computing platform 810 comprises a hardware architecture of processors, memory, etc., which is configured to control the execution of quantum applications, and interface with the control system 820 to (i) generate digital control signals that are converted to analog microwave control signals by the control system 820, to control operations of the quantum processor 830 when executing a given quantum application, and (ii) to obtain and process digital signals received from the control system 820, which represent the processing results generated by the quantum processor 830 when executing various gate operations for a given quantum application.

In some exemplary embodiments, the quantum computing platform 810 of the quantum computing system 800 may be implemented using any suitable computing system architecture which is configured to implement methods to support quantum computing operations by executing computer readable program instructions that are embodied on a computer program product which includes a computer readable storage medium (or media) having such computer readable program instructions thereon for causing a processor to perform control methods as discussed herein.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A package structure, comprising:
a first quantum bit chip and a second quantum bit chip bonded to an interposer; and
a differential coupling bus configured to differentially couple the first quantum bit chip and the second quantum bit chip at least in part through differential transmission lines disposed on the interposer.

2. The package structure of claim 1, wherein the differential coupling bus further comprises galvanic connections between the differential transmission lines and at least one of the first quantum bit chip and the second quantum bit chip.

3. The package structure of claim 1, wherein the differential coupling bus further comprises a non-galvanic connection between the differential transmission lines and at least one of the first quantum bit chip and the second quantum bit chip.

4. The package structure of claim 3, wherein:
the non-galvanic connection comprises a differential coupling capacitor connected to the differential transmission lines; and
the differential coupling capacitor is aligned to superconducting pads of a first quantum bit on the first quantum bit chip to implement a vacuum gap capacitor which provides the non-galvanic connection.

5. The package structure of claim 1, wherein the differential coupling bus comprises a tunable coupler that is configured to control interactions between a first quantum bit on the first quantum bit chip and a second quantum bit on the second quantum bit chip.

6. The package structure of claim 5, wherein:
the differential coupling bus comprises a first electrical path and a second electrical path which are configured to differentially couple the first quantum bit and the second quantum bit;
the tunable coupler is serially disposed in the first electrical path; and
the tunable coupler is capacitively coupled to the second electrical path.

7. The package structure of claim 6, wherein:
the second electrical path is coupled to a capacitor electrode;
the tunable coupler comprises a superconducting pad; and
the capacitor electrode and the superconducting pad of the tunable coupler comprise an interdigitated coplanar capacitor.

8. The package structure of claim 5, wherein the tunable coupler comprises a flux-tunable quantum bit.

9. A package structure, comprising:
a first quantum bit comprising a first pad and a second pad;
a second quantum bit comprising a third pad and a fourth pad; and
a differential coupling bus configured to differentially couple the first quantum bit and the second quantum bit;
wherein the differential coupling bus comprises:
a first electrical path which capacitively couples the first pad and the third pad;
a second electrical path which capacitively couples the third pad and the fourth pad;
the first electrical path comprises a tunable coupler, which is serially connected in the first electrical path, and which is configured to control interactions between the first quantum bit and the second quantum bit; and
the second electrical path is capacitively coupled to the tunable coupler.

10. The package structure of claim 9, wherein the tunable coupler comprises a flux-tunable quantum bit.

11. The package structure of claim 10, wherein:
the second electrical path is connected to a capacitor electrode;
the tunable coupler comprises a superconducting pad; and
the capacitor electrode and the superconducting pad of the tunable coupler comprise a coplanar capacitor that is configured to capacitively couple the second electrical path to the tunable coupler.

12. The package structure of claim 11, wherein the coplanar capacitor comprises an interdigitated coplanar capacitor.

13. The package structure of claim 9, wherein:
the first quantum bit is disposed on a first quantum bit chip;
the second quantum bit is disposed on a second quantum bit chip;
the first quantum bit chip and the second quantum bit chip are bonded to an interposer; and
at least a portion of the differential coupling bus comprises differential transmission lines disposed on the interposer.

14. The package structure of claim 13, wherein:
the first electrical path comprises a first bump connection between the first quantum bit chip and a first line of the differential transmission lines on the interposer, and a second bump connection between the second quantum bit chip and the first line of the differential transmission lines on the interposer; and
the second electrical path comprises a third bump connection between the first quantum bit chip and a second line of the differential transmission lines on the interposer, and a fourth bump connection between the second quantum bit chip and the second line of the differential transmission lines on the interposer.

15. A package structure, comprising:
a first quantum bit comprising a first pad and a second pad;
a second quantum bit comprising a third pad and a fourth pad;
a tunable coupler that is configured to control interactions between the first quantum bit and the second quantum bit; and
a differential coupling bus coupled to and between the first quantum bit and the second quantum bit, wherein the differential coupling bus comprises a first electrical path which capacitively couples the first pad and the third pad, and a second electrical path which capacitively couples the third pad and the fourth pad;
wherein the tunable coupler is capacitively coupled to both the first electrical path and the second electrical path.

16. The package structure of claim 15, wherein:
the tunable coupler comprises a first pad and a second pad;
the first pad of the tunable coupler is capacitively coupled to the first pad of the first quantum bit; and
the second pad of the tunable coupler is capacitively coupled to the second pad of the first quantum bit.

17. The package structure of claim 16, wherein:
the first quantum bit is disposed on a first quantum bit chip;
the second quantum bit is disposed on a second quantum bit chip;
the first quantum bit chip and the second quantum bit chip are bonded to an interposer; and
at least a portion of the differential coupling bus comprises differential transmission lines disposed on the interposer.

18. The package structure of claim 17, wherein:
the interposer comprises a first differential coupling capacitor connected to the differential transmission lines;
the first differential coupling capacitor comprises first and second electrodes that are aligned to the first and second pads of first quantum bit on the first quantum bit chip to implement a vacuum gap capacitor which provides a non-galvanic connection between the differential coupling bus and the first quantum bit.

19. The package structure of claim 18, wherein:
the interposer comprises a second differential coupling capacitor connected to the differential transmission lines;
the second differential coupling capacitor comprises first and second electrodes that are aligned to the first and second pads of second quantum bit on the second quantum bit chip to implement a vacuum gap capacitor which provides a non-galvanic connection between the differential coupling bus and the second quantum bit.

20. The package structure of claim 19, further comprising:
a first bump bond and second bump bond, which provide galvanic connections between the differential transmission lines on the interposer and a first capacitor electrode and a second capacitor electrode on the second quantum bit chip;
wherein the first capacitor electrode is capacitively coupled to the third pad of the second quantum bit; and
wherein the second capacitor electrode is capacitively coupled to the fourth pad of the second quantum bit.
